(19) United States
(12) Patent Application Publication
(10) Pub. No.: US 2004/0187060 A1
(43) Pub. Date: Sep. 23, 2004

(54) Generating test patterns for testing an integrated circuit

(76) Inventors: John G. Rohrbaugh, Ft. Collins, CO (US); Jeff Rearick, Ft. Collins, CO (US)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/393,844

(22) Filed: Mar. 21, 2003

(51) Int. Cl. G06F 11/00; G01R 31/28

(52) U.S. Cl. 714/742

(57) ABSTRACT

Systems and methods for generating test patterns are disclosed herein. One such test pattern generating method comprises receiving a netlist of a device under test (DUT), the netlist comprising regions bounded by control/observe points. At least one of the bounded regions is embedded within another bounded region. The method further comprises generating test patterns for the bounded regions using a sequence starting with the deepest embedded bounded regions.

### TECHNICAL FIELD

The present disclosure generally relates to testing of integrated circuits. More particularly, the disclosure relates to systems and methods for generating test patterns used to test integrated circuits.

### BACKGROUND

As integrated circuits (ICs) are fabricated, defects on the ICs may arise due to unavoidable errors in the fabrication process. To determine the quality of each of the ICs being fabricated, testing can be performed on the IC at the wafer-level or after the wafer has been diced into individual ICs. Normally, testing is performed by first generating test patterns of a model IC during a first process. During a second process, the test patterns are used to test a large group of ICs having the same circuitry as the model. Once the test patterns are generated for a model IC, the same test patterns can be repeated for any of the same ICs.

For simple ICs, such as those with about 10, 12 or 14 input and output pins, generating test patterns is a relatively simple task that can normally be done by human calculations. However, as ICs have become more and more complex, such as with system on chip (SOC) ICs, generating test patterns, for all practical purposes, requires a computer. For example, a complex IC may have hundreds of input and output pins and millions of internal gates. Calculating test patterns for such an IC is computationally daunting and requires a great amount of time, even for high-speed computers.

To simplify the testing of ICs, IC designers use a “design for testability” scheme that involves designing an IC such that it not only performs its intended purposes, but also is configured such that it can be tested more thoroughly and with greater ease. For example, one such design for testability scheme is “scan testing.” Since most ICs typically have too few input and output ports or pins to practically test the millions of internal gates, scan testing allows a tester to insert test patterns into the internal structure of the IC. To design an IC with scan testing, the designer connects most or all of the internal flip-flops together in a chain, or using a shift register, and the ends of the chain or shift register are connected to the ports or pins of the IC. Test patterns can then be serially inserted in a scan input port connected to one end of the chain to shift data into the middle of the IC. Output results can also be serially read from the other end of the chain at an output scan port. If more input and output ports or pins are available on the IC, a long chain can be broken up into smaller chains.

FIG. 1 is a simple block diagram of an IC 10 having conventional scan testing available for testing the IC 10. The IC 10 includes any number of ports 12, depending on the particular design. To enable scan testing, the IC 10 contains a port 12 configured as a “SCAN ENABLE” input that, when activated, switches the IC 10 to a scan test mode. The IC 10 further includes ports 12 that are used as “SCAN INPUT” and “SCAN OUTPUT” terminals. During the scan test mode, test patterns may be input into the SCAN INPUT and test results may be read from the SCAN OUTPUT. During normal operation, the SCAN INPUT and SCAN OUTPUT ports may additionally be used as regular I/O ports for the IC 10. In addition to their use during normal operation, the remaining ports 12 may also receive test patterns during the scan test.

FIG. 2 is a block diagram of an IC 14 with a conventional scan testing configuration. The test pattern is input into the SCAN INPUT and is read into an input scan chain 16. The input scan chain 16 may include a chain of connected flip-flops, a scannable shift register, a scan register, or other alternative data shifting device. The input scan chain 16 serially receives the test pattern into its plurality of registers and outputs a plurality of bits from the registers to portions of a logic circuit 18 being tested. In order to align the test pattern with the respective bit inputs of the logic circuit 18, the order of the portions of the logic circuit 18 corresponding to the registers and the number of bit shifting sequences is known. Outputs from the logic circuit 18 are sent to an output scan chain 20, which may be a chain of flip-flops, a scannable shift register, a scan register, or other suitable data shifting device. The input scan chain 16 and the output scan chain 20 may be configured together as one chain, as described below. The output scan chain 20 outputs a serial stream of data representing the test results from the scan test onto the SCAN OUTPUT. In addition to the input scan chain 16 and the output scan chain 20, the logic circuit 18 may also be connected to other circuitry 22 as well.

FIG. 3 is a block diagram of the internal structure of the IC 14 of FIG. 2 in which the input scan chain 16 and output scan chain 20 are formed together as a linear feedback shift register 24 having a chain of flip-flops 26. The flip-flops 26 are connected together with multiplexers 28 between them. When the scan test mode is enabled by activating the SCAN ENABLE, the first multiplexer 28 selects its input from the SCAN INPUT. The second multiplexer 28 selects its input from the previous flip-flop 26, and so on. The flip-flops 26 are clocked a number of times until the serial stream of SCAN INPUT data is clocked into all of the flip-flops 26. On the next CLK signal, the flip-flops 26 transmit the test patterns into the portions of the logic circuit 18 under test. The outputs of the logic circuit 18 in response to the applied test patterns are read back onto the multiplexers 28 and the test results are serially shifted out of the SCAN OUTPUT at the output of the linear feedback shift register 24.

To generate the test patterns that may be used for testing an IC, such as the test patterns applied to the SCAN INPUT of the IC 10 of FIG. 1 or the IC 14 of FIGS. 2 and 3, a “netlist” or model of the IC design is created. The netlist typically contains all of the structural or physical components, gates, circuitry, etc. at the lowest level of the IC and the connections or “connectivity” between the components. The netlist, along with other testability commands, is transmitted to an automatic test pattern generator (ATPG). The testability commands or features include information about where the scan inputs and outputs are located on the IC, where the scan enable (or test mode enable) is located, where the scan clock is located, etc. With the netlist and testability commands, the ATPG determines the order of the scannable flip-flops in the chain, generates the test patterns that are input into the IC, and calculates the desired test results at the output of the tested IC.

One problem with conventional ATPGs is that they use a process involving complex algorithms that become exponentially more complex with the addition of more inputs, outputs, and gates. With conventional ATPGs, it may take hours, days, or even weeks to generate acceptable test patterns for complex ICs. Furthermore, ATPGs typically need a large amount of memory to run the complex algorithms. Thus, a need exists in the industry to address the aforementioned and/or other deficiencies and/or inadequacies.

### SUMMARY

The present disclosure includes systems and methods for generating test patterns. One embodiment of a test pattern generating method comprises receiving a netlist of a device under test (DUT), whereby the netlist comprises regions that are bounded by control/observe points. Of the bounded regions, at least one bounded region is embedded within another bounded region. The method further includes generating test patterns for the bounded regions using a sequence starting with the deepest embedded bounded regions and proceeding to the surrounding bounded regions.

Other systems, methods, features, and advantages of the present disclosure will be apparent to one having skill in the art upon examination of the following drawings and detailed description. It is intended that all such additional systems, methods, features, and advantages be included within this description and protected by the accompanying claims.

### BRIEF DESCRIPTION OF THE DRAWINGS

Many aspects of the embodiments disclosed herein can be better understood with reference to the following drawings. Like reference numerals designate corresponding parts throughout the several views.

FIG. 1 is a block diagram of a conventional integrated circuit (IC) having scan testing incorporated therein to aid in testing the IC.

FIG. 2 is a block diagram of another conventional IC showing a conventional scan testing circuit.

FIG. 3 is a block diagram of the IC of FIG. 2 showing another conventional scan testing circuit using a linear feedback shift register.

FIG. 4 is an illustration showing an example of a hierarchically designed device under test (DUT).

FIG. 5 is an illustration of an example of a region on a DUT bounded by control/observe points.

FIG. 6 is a block diagram of an embodiment of a testing system.

FIG. 7 is a block diagram of an embodiment of the test pattern processing system shown in FIG. 6.

FIG. 8 is an illustration of an example mapping diagram showing the location of bounded regions on an example DUT.

FIGS. 9A-9D are illustrations of example mapping diagrams showing an embodiment for separating layers of bounded regions of the example of FIG. 8 according to a first layering scheme based on bounded regions being embedded within other bounded regions.

FIG. 10A-10D are illustrations of example mapping diagrams showing another embodiment for separating layers of bounded regions of the example of FIG. 8 according to a second layering scheme based on bounded regions being embedded within other bounded regions.

FIG. 11 is a flow chart illustrating an embodiment of a method for generating test patterns.

FIG. 12 is a flow chart illustrating another embodiment of a method for generating test patterns.

FIG. 13 is a flow chart illustrating yet another embodiment of a method for generating test patterns.

FIGS. 14A and 14B are combined to form a flow chart illustrating another embodiment of a method for generating test patterns.

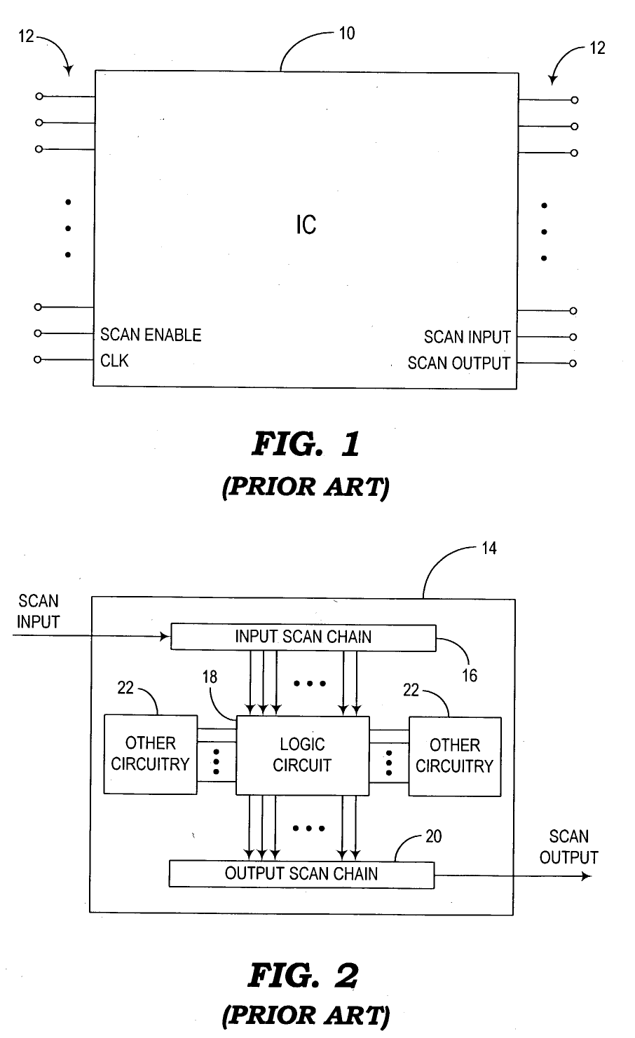

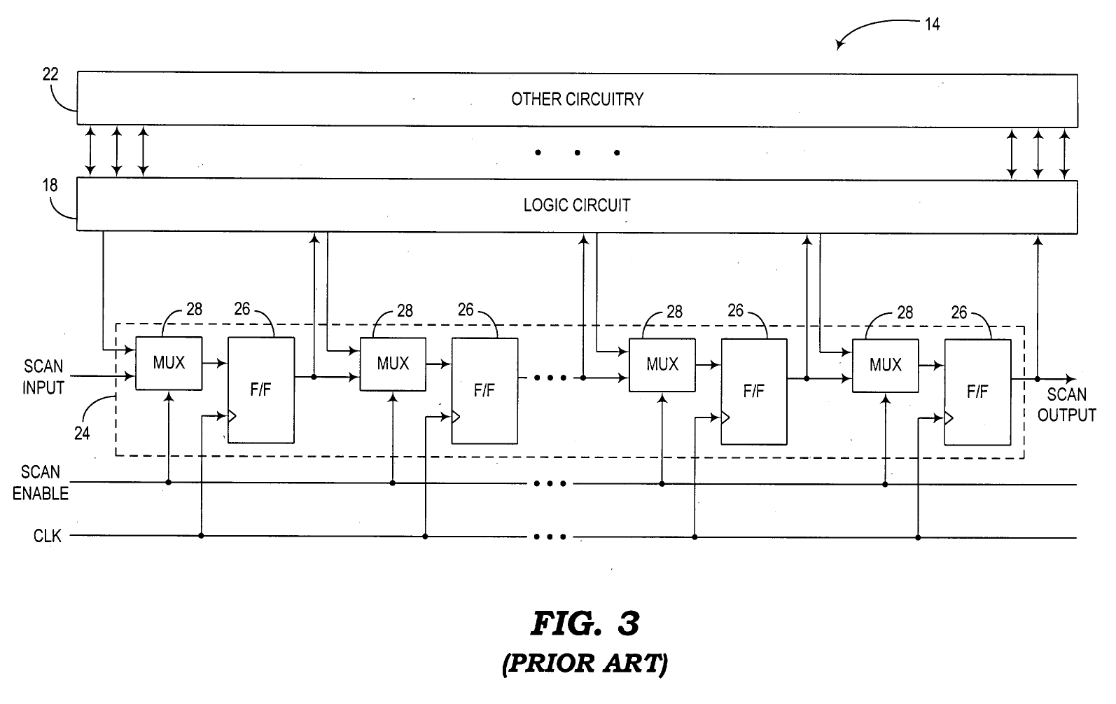

### DETAILED DESCRIPTION

Test pattern processing systems and methods are disclosed herein for generating and handling test patterns that are used for testing a device under test (DUT), such as an integrated circuit (IC). A conventional method of generating test patterns involves using an automatic test pattern generator (ATPG) to generate test patterns for the entire IC in one ATPG run. Instead of generating test patterns for the whole IC, the systems and methods of the present disclosure break the process down into parts that are more manageable. As mentioned earlier, conventional ATPGs use algorithms having a complexity on the order of an exponentially increasing factor based on the number of inputs and outputs of the DUT and the number of components within the DUT. By breaking the process down into parts, the process is significantly simplified and the ATPG can run more efficiently, thereby reducing the ATPG run time.

The test pattern processing systems and methods involve breaking down the IC design such that smaller portions of the entire netlist are fed to the ATPG. The ATPG runs for each portion of the design starting with the lowest level of the design and working up to the top level, which includes the entire design. A first technique for breaking down the IC design includes maintaining the “hierarchy” that is typically used when designing ICs. The term “hierarchy” refers to the levels of blocks of a design in which each higher level block includes a plurality of smaller blocks or sub-blocks that are a subset of the higher level block.

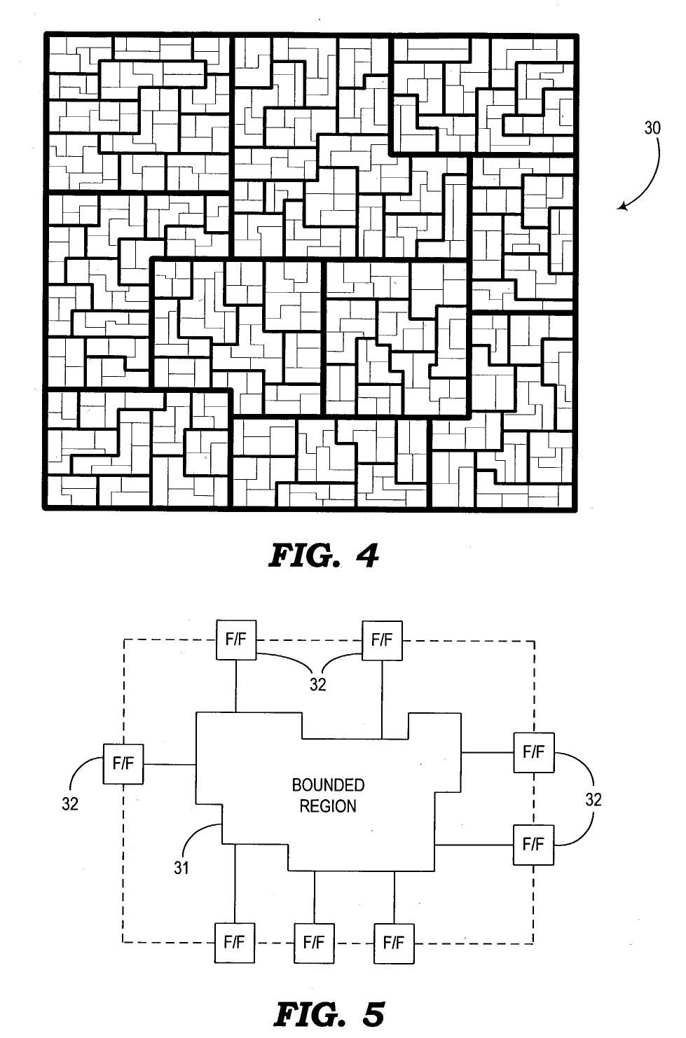

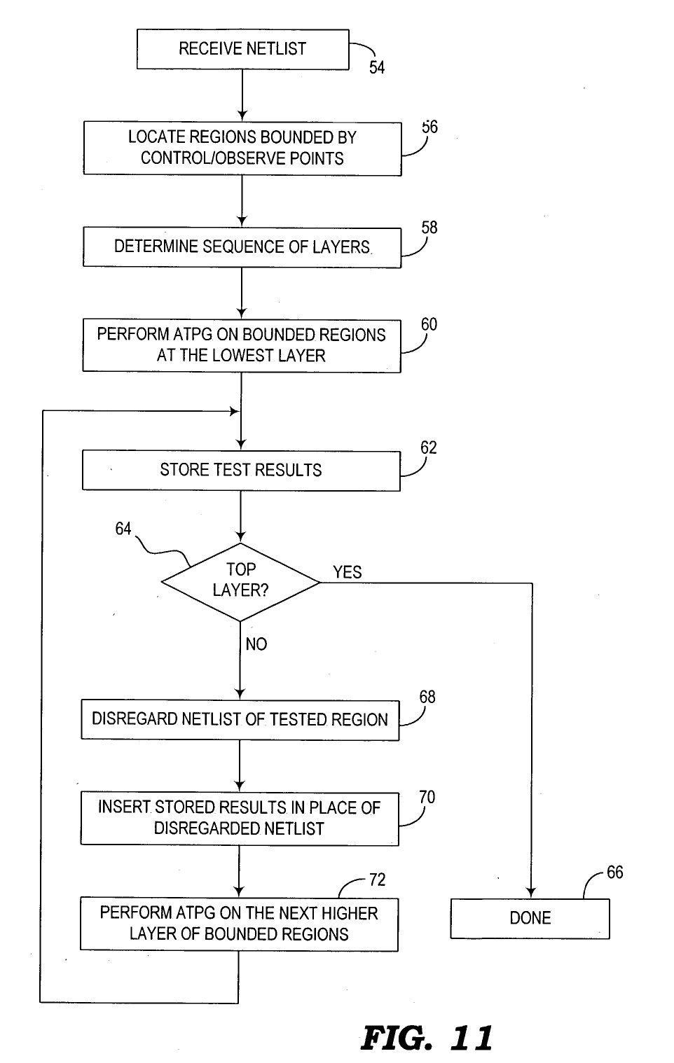

FIG. 4 illustrates an example of hierarchy in which a DUT 30, e.g. an IC, includes any number, e.g. about 5 to 30, major blocks or circuits, which are outlined in the drawing with thick lines. In this example, ten major blocks are shown in FIG. 11. These major blocks are the top level of the hierarchy making up the whole DUT 30. Each major block can then be designed having any number, e.g. about 5 to 30, sub-blocks or sub-circuits, outlined by medium lines. The sub-blocks can have a number of sub-sub-blocks, outlines by thin lines, and this dividing and sub-dividing process is repeated all the way down to the lowest level logic gates. All in all, the DUT 30 may have several levels of blocks throughout the hierarchy and millions of logic gates at the lowest level of blocks. The term “block” is used herein to refer to any level of the major blocks, sub-blocks, sub-sub-blocks, etc. By maintaining this hierarchy used in designing the DUT 30, the test patterns can be generated for each individual block.

A second technique for breaking down the IC design involves locating “bounded regions” in the design of the IC. A “bounded region” refers to an area in the design of the IC that is enclosed or encircled by control/observe points. In other words, a “bounded region” has no communication with circuitry outside the region except through control/observe points. The term “control/observe points” refers to any combination of scannable flip-flops, terminals, pins, ports, etc. that can be accessed from the primary input and/or output ports or pins of the IC. These primary input and/or output ports may include input/output (I/O) terminals, inputs, outputs, scan inputs, scan outputs, etc. The bounded regions may extend across the blocks, sub-blocks, etc. of the hierarchy and can even extend across blocks in different levels of the hierarchy.

FIG. 5 illustrates an example of a bounded region 31 completely surrounded by control/observe points 32. In this example, the control/observe points 32 are shown as flip-flops. However, the control/observe points 32 may also contain the input or output ports of the IC or other accessible port, terminal, pin, pad, etc. Generally speaking, a control/observe point 32 is a terminal that can be accessed from the ports of the IC, either through scan testing or by direct input from a primary input or output. The bounded region 31 is in communication with outside circuitry only through the control/observe points 32.

The test pattern processing systems and methods utilize the ATPG in such a way that the ATPG generates test patterns for each portion of the IC netlist as if each portion itself is the netlist of an entire IC. In this regard, one portion at a time can be fed to the ATPG in order that the ATPG may perform test pattern generation in layers. Starting at a lower layer, the ATPG generates the test patterns for the portion of the netlist at the lower layer. The results can be applied to the next higher layer for larger portions that encompass at least one smaller portion. The ATPG runs can be repeated up the different layers until the entire IC is tested.

The test pattern processing systems and methods can simplify the test pattern generating process by applying the same test patterns to two like regions. In the case of the regions bounded by control/observe points, if two regions have the same circuit components and connectivity, then one region can adopt the test patterns of the other. In the case of the hierarchical blocks, if two blocks have the same components and connectivity, then one block can adopt the test patterns of the other.

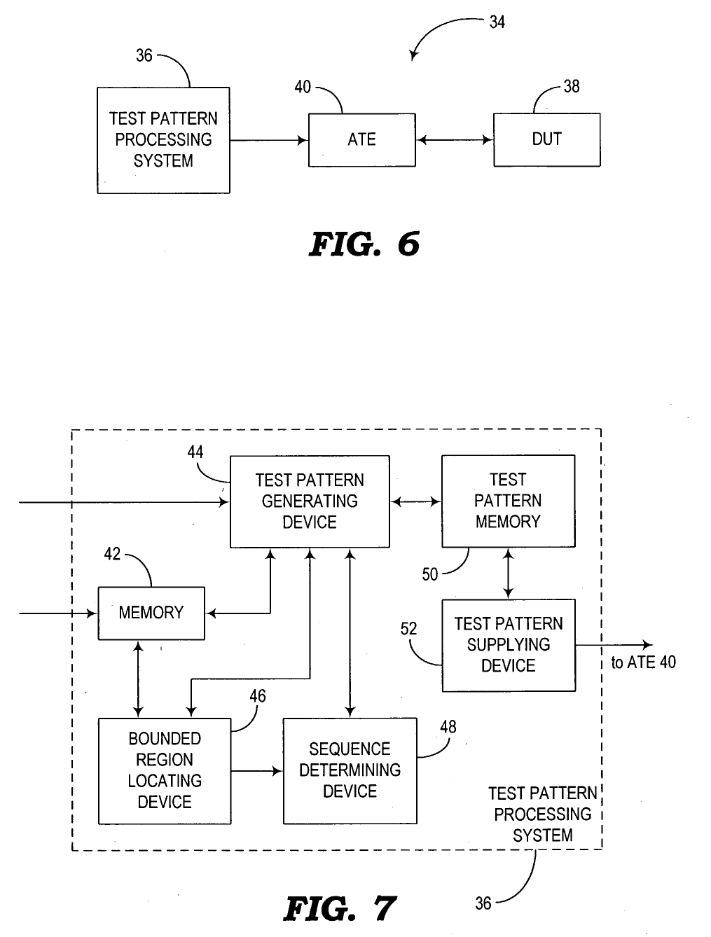

FIG. 6 is a block diagram of an embodiment of a testing system 34 using test patterns. A test pattern processing system 36 receives a model, i.e. netlist, of DUT 38, such as an IC or other electronic or electrical component, circuit, or system. The test pattern processing system 36 generates test patterns that may be used for testing any DUTs having the same configuration as the model. The generated test patterns are created in layers and stored in a memory device within the test pattern processing system 36. The test pattern processing system 36 retrieves the test patterns from the memory device and supplies the test patterns to automatic testing equipment (ATE) 40 for testing the DUT 38. The ATE 40 includes coupling devices for applying the test patterns to the DUT 38. The ATE 40 then receives output signals from the DUT 38 that indicate its condition. The testing system 34 may be used to test an IC at the wafer-level, the diced, unpackaged-level, and/or the package-level. After testing, the ATE 40 may perform post-testing procedures based on the results of the tests.

The test pattern processing system 36 can be implemented in hardware, software, firmware, or a combination thereof. In the disclosed embodiments, the test pattern processing system 36 is implemented in software or firmware that is stored in a memory and that is executed by a suitable instruction execution system. If implemented in hardware, as in an alternative embodiment, the test pattern processing system 36 can be implemented with any or a combination of the following technologies, which are all well known in the art: a discrete logic circuit having logic gates for implementing logic functions upon data signals, an application specific integrated circuit (ASIC) having appropriate combinational logic gates, a programmable gate array (PGA), a field programmable gate array (FPGA), etc.

FIG. 7 is a block diagram of an embodiment of the test pattern processing system 36 shown in FIG. 6. The test pattern processing system 36 includes a memory 42 that receives the netlist. As mentioned earlier, the netlist is a model of the DUT for which test patterns are to be generated. A test pattern generating device 44, such as an ATPG, receives testability commands etc. and can retrieve the netlist from the memory 42. A bounded region locating device 46 also has access to the netlist stored in the memory 42. The bounded region locating device 46 retrieves the netlist and detects the location of the regions in the circuit design of the IC that are completely surrounded by control/observe points.

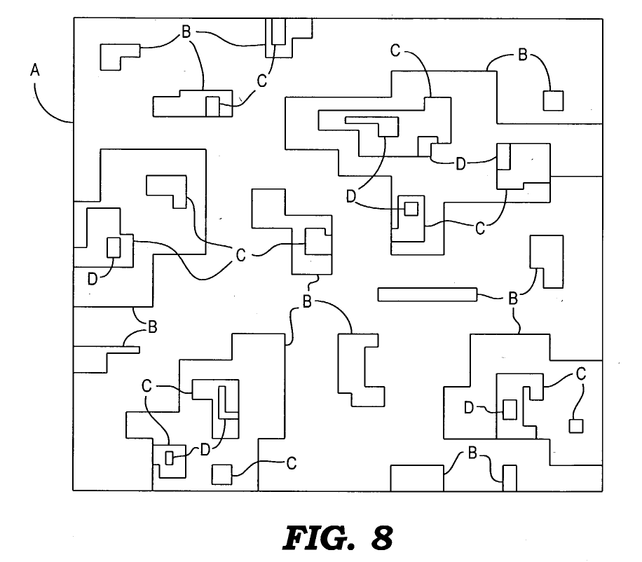

FIG. 8 is an illustration of an example of a mapping diagram showing the location of the bounded regions detected in the design of a hypothetical DUT. The mapping diagram of the embedded regions may be detected by the bounded region locating device 46. The reference character “A” represents the top layer indicating the entire DUT, which is, in fact, bounded by the ports of the IC. Reference character “B” represents the next lower layer of bounded regions that are embedded within “A.” Embedded within some portions of the “B” layer are bounded regions designated by “C.” Some C layer regions embed other bounded regions at alower layer, which is represented by “D.” Although layers A, B, C, and D are shown in this example, it should be noted that there may be fewer or more layers, and the layers can have any shape and/or size. It should further be noted that some embedded regions share a portion of the boundary with the higher layer region. In this case, the control/observe points are the same and may be used at each layer.

Referring back to FIG. 7, after the bounded region locating device 46 locates the bounded regions, the mapping diagram of the bounded regions is sent to the test pattern generating device 44 and to a sequence determining device,48. The sequence determining device 48 determines a layering scheme based on the bounded regions. For example, if a particular bounded region, e.g. on the C layer, is embedded within another bounded region, e.g. on the B layer, the embedded bounded region is tested first before the surrounding bounded region is tested, since the surrounding bounded region relies upon the test pattern results from the embedded region. The sequence determining device 48 provides a sequence of layers based on the layers of embedding. Testing proceeds from the lowest layer to the highest layer.

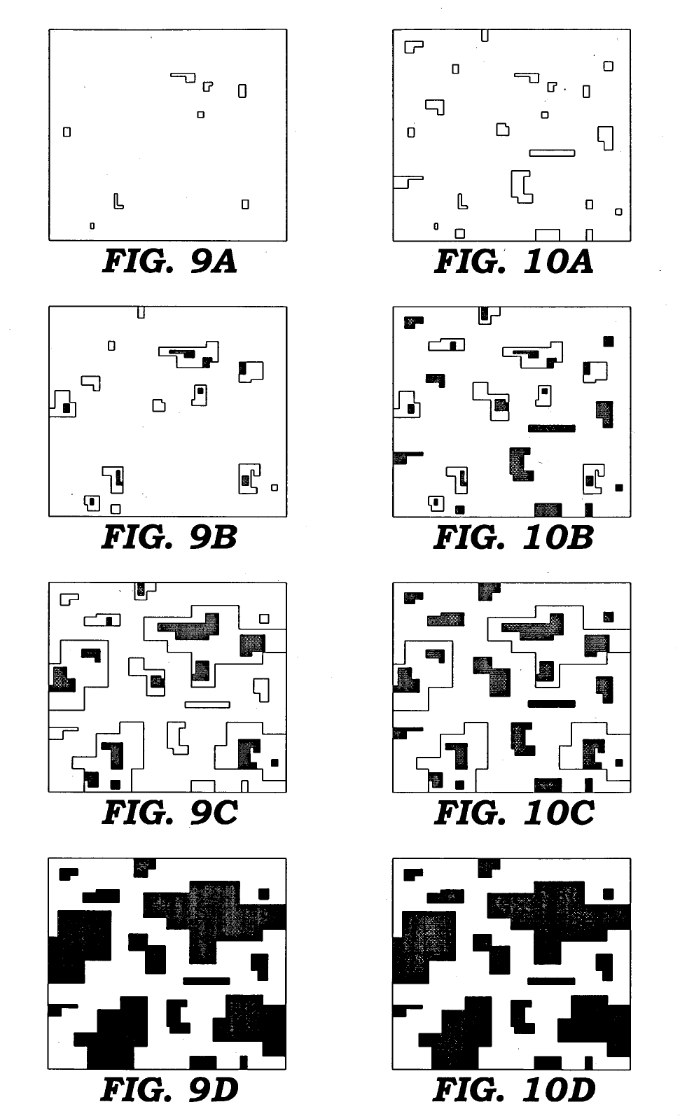

FIGS. 9A through 9D are illustrations of an embodiment of a layering scheme showing the four layers of the example shown in FIG. 8 as determined by the sequence determining device 48. FIG. 9A shows the D layer portions, which are the bounded regions embedded deepest within other bounded regions. This figure shows the small portion of the overall circuit that is tested in the first stage of test pattern generation. Test patterns can be generated for this portion using any test pattern generator, such as the testing pattern generating device 44 shown in FIG. 7. Since all of the inputs and outputs of the bounded regions are control/observe points, testing can be performed on each bounded region independently from the rest of the DUT. The netlist encompassed within the bounded regions at each layer are provided to the test pattern generating device 44 for generating test patterns for these portions. When the test results from this small portion are complete, the netlist for this portion can be disregarded or even removed from the memory 42 and the test pattern results can be inserted in its place to be used at the next higher layer.

FIG. 9B shows the C layer of bounded regions. With the netlist of the D layer removed from the C layer portions that have embedded D layer portions within, test patterns are generated for the C layer. In these figures, the shaded areas represent the portions of the netlist that have been removed during a lower layer test. The generation of test patterns is greatly simplified because of the removal of the D layer netlist. Since test pattern generators use algorithms that increase in complexity by an exponential factor, based on the size of the netlist, the removal of the netlist of the lower layer, i.e. the D layer, simplifies the test pattern generator and increases efficiency.

FIG. 9C shows the B layer with the C and D layers removed. Again, the algorithms run on the B layer are greatly simplified because of the removal of the lower layers. When the B layer of the test patterns are calculated, the B layer netlist is removed from the A layer, as shown in FIG. 9D, which shows the entire DUT. The A layer test patterns are generated with the netlist of the B, C, and D layers removed and the test pattern results from the lower layer ATPG runs inserted.

FIGS. 10A through 10D show examples of an alternative embodiment for performing test pattern generation of the example of bounded regions shown in FIG. 8. For example, the sequence determining device 48 may calculate a sequence of test pattern generation in which portions of different layers may be performed simultaneously. For instance, the example of FIG. 8 includes some B layer regions that have no embedded bounded regions therein. In this case, this B layer may be processed at the same time as the D layers since it does not depend on the test pattern results of embedded regions. Likewise, C layers that do not have D layer regions embedded therein may be processed at the same time as well.

FIG. 10A shows a first round of testing based on this alternative sequencing or layering scheme. The netlist for the tested regions are removed and the test pattern results are applied to the next higher layer for the next round shown in FIG. 10B. The next higher layer is tested using the test results from the previous round, if necessary. After this test, the netlist of the tested regions are removed for the next round as shown in FIG. 10C. This process is repeated again for the A layer test shown in FIG. 10D.

Referring again to FIG. 7, the sequence determining device 48 sends the testing sequence of the different layers to the test pattern generating device 44. Therefore, the test pattern generating device 44 receives commands at a first input, the netlist from the memory 42 at a second input, bounded regions from the bounded region locating device 46 at a third input, and a layering sequence from the sequence determining device 48 at a fourth input. When these inputs are received, the test pattern generating device 44 performs a test pattern generating algorithm, such as an ATPG algorithm, according to the layering sequence dictated by the sequence determining device 48. A first layering scheme, as mentioned above, involves generating test patterns for the D layer as shown in FIG. 9A, applying the D layer test to the next higher layer to generate test patterns for the C layer as shown in FIG. 9B, applying the C layer test to the next higher layer to generate test patterns for the B layer as shown in FIG. 9C, and finally applying the B layer test to the next higher layer to generate test patterns for the A layer. A second layering scheme for generating test patterns at the different layers is mentioned above with respect to FIGS. 10A through 10D. Techniques, other than those described with respect to FIGS. 9 and 10, may alternatively be used to test the DUT in layers based on a sequence in which the embedded bounded regions on the lowest layer are processed first and the highest layer is processed last after all of the embedded regions have been processed.

The test pattern generating device 44 retrieves the netlist for a first layer, i.e. the lowest layer. Since the first layer may contain several independent bounded regions, testing of each region may be done in sequence, simultaneously using separate processors, or some combination of the two. When the test pattern generating device 44 generates test patterns for this layer, the test patterns are stored in a test pattern memory 50.

The test pattern generating device 44 moves to the next higher layer based on the input from the bounded region locating device 46 and the sequence determining device 48. The test pattern generating device 44 also retrieves the netlist for this next layer from memory 42 and receives test patterns from the test pattern memory 50 to determine which portions of the netlist have already been tested and can therefore be disregarded. The test pattern generating device 44 generates test patterns for this layer and stores the test patterns in the test pattern memory 50. This process is repeated for the next higher layer and continues up the layers until the highest layer is reached. When the top layer is tested, much of the netlist from the lower layers has been removed and generating test patterns is thereby greatly simplified. A test pattern supplying device 52 retrieves the test patterns from the test pattern memory 50 and supplies the test patterns to the ATE 40, which uses the test patterns to actually test the DUT 38.

FIG. 11 is a flow chart illustrating an embodiment of a method for generating test patterns. In process block 54, the netlist, or circuit design model, of the DUT, is received. In process block 56, the netlist is analyzed in order to locate regions of the circuit design that are bounded by control/observe points. In process block 58, the bounded regions are analyzed to determine if some bounded regions are embedded within other bounded regions. With the layers of embedding, a sequence is determined in which the layers may be processed to maximize the efficiency of the ATPG. In process block 60, ATPG is performed on the bounded regions at the lowest layer and the test pattern results are stored, as indicated in process block 62.

In decision block 64, it is determined whether or not the top layer has been reached. If so, then flow proceeds to process block 66, where the test pattern generating method is completed. If the top layer has not been reached, then flow proceeds to process block 68, where the netlist of the tested regions is disregarded in the next higher level. The netlist of the tested regions may be ignored or even eliminated or removed from memory. In process block 70, the stored test pattern results are inserted in place of the netlist that was disregarded. In process block 72, ATPG is performed on the bounded regions at the next higher layer. Flow then proceeds to process block 62, and process blocks 62, 64, 68, 70, and 72 are repeated until the top level is reached.

With the hierarchical design shown in FIG. 4, methods are described for generating test patterns while maintaining this hierarchy. In these methods, ATPG is run on “blocks” instead of regions bounded by control/observe points, as described above. Test patterns are generated for lower level blocks first and then calculated for higher level blocks. The hierarchy of the blocks is maintained, which is different from the prior art method in which the hierarchy is ignored and the IC as a whole is tested. A first method includes automatically augmenting the test patterns, when necessary, if a block includes inaccessible terminals. In this embodiment, the inaccessible terminals are terminals that cannot be accessed from the I/Os, inputs, outputs, scan inputs, scan outputs, etc. of the IC. A second method includes intentionally binding or surrounding some or all of the blocks by control/observe points.

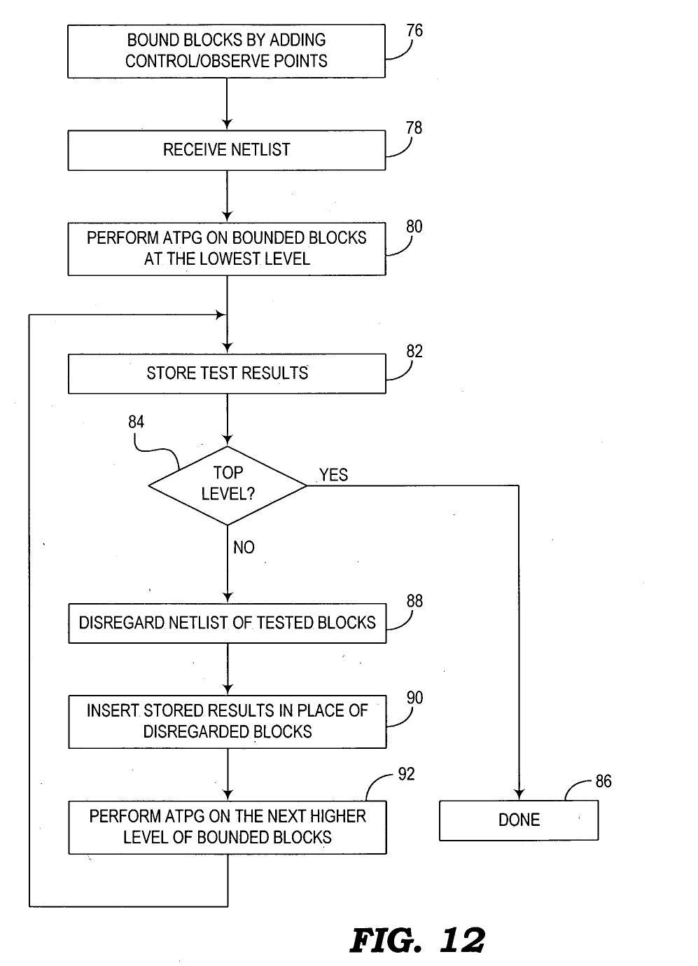

FIG. 12 is a flow chart of an embodiment of a method for generating test patterns by systematically binding the blocks. This block binding embodiment includes designing the IC such that control/observe points are placed around the blocks at any or all levels of the hierarchy. Depending on timing and/or area constraints, control/observe points are added where possible or practical in order to make the blocks “bounded regions.” In process block 76, the blocks are intentionally bound by adding control/observe points, such as flip-flops or other suitable accessible terminals, during the design stage. Preferably, the blocks are bound such that the netlists in each block are substantially the same size in order that ATPG is run on approximately equal-sized netlists, thus improving efficiency. In process block 78, a netlist created from a model of the designed IC is received. In process block 80, ATPG is performed on the bounded blocks at the lowest level of the blocks in the hierarchy. In process block 82, the test results of the generated test patterns are stored.

In decision block 84, it is determined whether or not test patterns for the top level of blocks have been generated. If the top level has been reached, then flow proceeds to process block 86, in which the test pattern generating method is finished. Otherwise, flow proceeds to process block 88, in which the netlist of the tested blocks is disregarded in the netlist at the next higher level. The netlist of the tested blocks may be ignored or removed from memory, if desired. In process block 90, the test patterns from previous runs are inserted in place of the netlist of the blocks that have been disregarded. By disregarding or eliminating blocks and inserting the generated test patterns, the process can be described as actively “flattening” the hierarchy. With the netlist reduced by previous runs and the test results inserted in place of disregarded netlist blocks, process block 92 includes performing ATPG on the next higher level of the bounded blocks. At this point, flow returns to process block 82 and process blocks 82, 84, 88, 90, and 92 are repeated until the top level is reached.

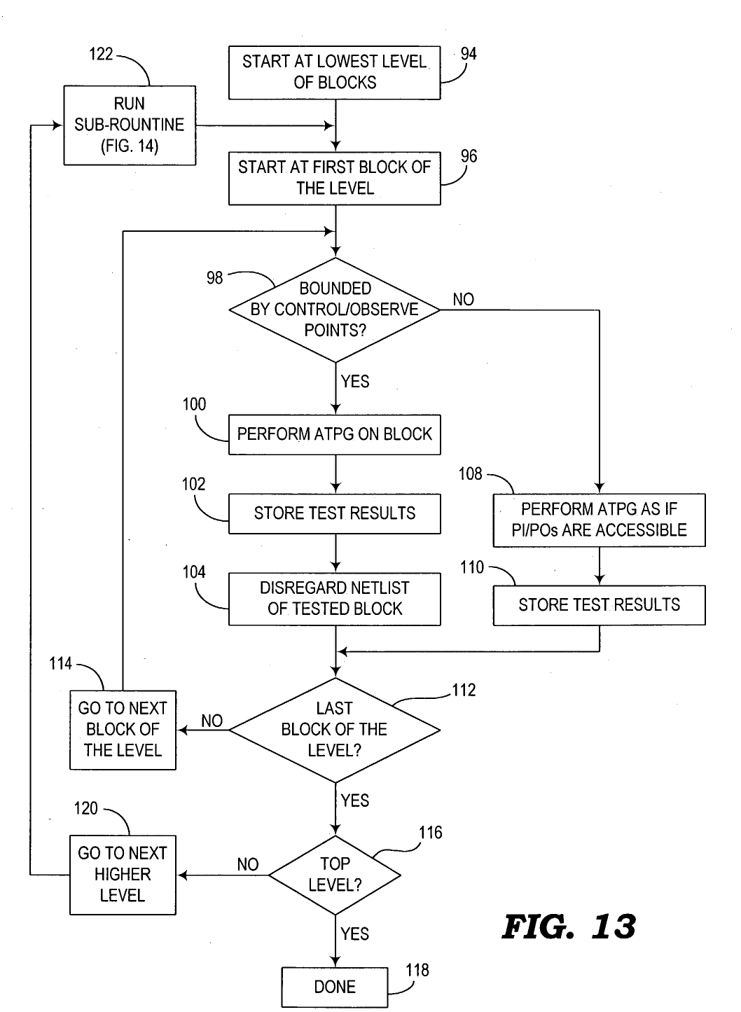

FIG. 13 is a flow chart of an embodiment of a method for generating test patterns. In this method, when blocks at lower levels include inaccessible terminals, the test patterns can be augmented at higher levels. In process block 94, the test pattern generating method starts at the lowest level of the blocks. The lowest level may be established according to pre-determined size criteria or other suitable automatically or manually established factors. In process block 96, the method starts at a first block of the lowest level. The first block can also be established by any type of suitable automatic or manual establishing means. Once the particular block of interest is established, flow proceeds to decision block 98.

In decision block 98, it is determined if the block of interest is bounded by control/observe points. If so, flow proceeds to a first branch, the first process block of which includes performing ATPG on the block, as described in process block 100. In process block 102, the test results from the ATPG run are stored. In process block 104, the netlist of the tested block is disregarded, or even removed or eliminated, from the netlist at the next higher block that embeds the tested block. At this point, flow proceeds to decision block 112.

If it is determined in decision block 98 that the block under test is not bounded by control/observe points, flow proceeds to process block 108. In process block 108, ATPG is performed as if all of the primary inputs and primary outputs (PI/POs) are accessible. Assumptions are made that the inaccessible PI/POs of the block at a lower level will be accessible at a higher level and that the inaccessible PI/POs will not be grounded, tied high, or allowed to float in the next higher level block. In process block 110, the test patterns are stored and flow proceeds to decision block 112.

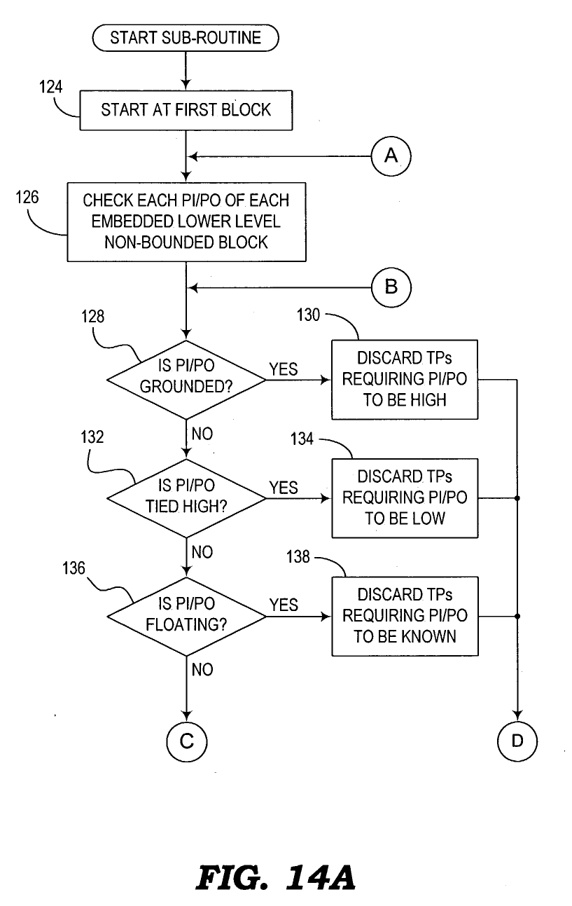

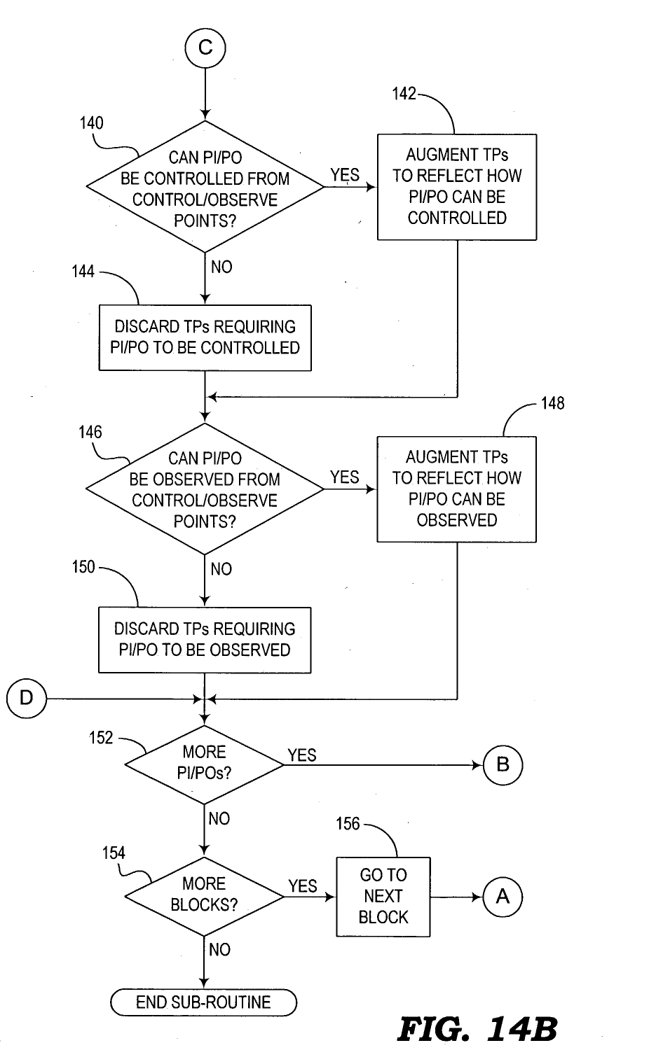

In decision block 112, it is determined whether or not the last block of the current level has been tested. If not, then flow proceeds to process block 114, in which the method proceeds to the next block of that level. At the next block in the level, the method loops back to decision block 98, which is repeated. If it is determined that the last block of the level has been tested in decision block 112, flow proceeds to decision block 116. In decision block 116, it is determined whether or not the top level has been reached. If so, flow proceeds to process block 118, where the method concludes. If it is determined that the top level has not been reached in decision block 116, flow proceeds to process block 120 in which the method proceeds to the next higher level of blocks, having completed a lower level. Flow then proceeds to process block 122, in which a sub-routine is performed. The sub-routine, as described below with respect to FIG. 14, determines if the blocks at the lower level contain primary inputs and primary outputs (PI/POs) that are absolutely inaccessible. If not, then the sub-routine augments or discards the test patterns if access to the PI/POs can be controlled or observed. When the sub-routine is complete, flow proceed back to process block 96 and the method is repeated for the blocks on the next higher level until all blocks on all levels have been tested.

FIGS. 14A and 14B, in combination, represent a flow chart of an embodiment of the sub-routine for discarding or augmenting primary inputs and primary outputs that are determined to be inaccessible at the immediately lower level. At the start of the sub-routine, the first block at the higher level is observed, as indicated in process block 124. In process block 126, each primary input and primary output of each non-bounded block on the lower level, which is embedded within the block at the higher level, is checked.

In decision block 128, it is determined whether or not a first primary input or primary output is grounded. If it is grounded, the test patterns that require that primary input or primary output to be high are discarded, as indicated by process block 130. Flow then proceeds to decision block 152 shown in FIG. 14B. If not grounded, the primary input or primary output is checked whether or not it is tied high, as indicated in decision block 132. If tied high, the test patterns requiring the primary input or primary output to be low are discarded, as indicated in process block 134, and flow proceeds to decision block 152. If not high in decision block 132, the primary input or primary output is checked whether or not it is disconnected and floating in decision block 136. If it is floating, then the test patterns requiring the primary input or primary output to be a known value (high or low) are discarded, as indicated in process block 138, and flow proceeds to decision block 152.

If the primary input or primary output (PI/PO) is not grounded, tied high, or floating, then flow proceeds to decision block 140 shown in FIG. 14B. Decision block 140 includes determining whether the PI/PO can be controlled from the control/observe points. If it can, then flow proceeds to process block 142 in which the test patterns (TPs) are augmented to reflect how the PI/PO can be controlled. Any suitable algorithm may be used to satisfy this augmentation of the test patterns. From process block 142, flow proceeds to process block 146. If the PI/PO cannot be controlled, as determined in decision block 140, then flow proceeds to process block 144, where the test patterns requiring the PI/PO to be controlled are discarded.

In decision block 146, it is determined whether the PI/PO can be observed from control/observe points. If it can, then the test patterns are augmented to reflect how the PI/PO can be observed, as indicated in process block 148. From process block 148, flow proceeds to decision block 152. If it is determined that the PI/PO cannot be observed in decision block 146, then the test patterns that require the PI/PO to be observed are discarded, as indicated in process block 150. In decision block 152, it is determined whether or not any more primary inputs and/or primary outputs are contained in the block. If so, the next PI/PO is considered and flow proceeds back to decision block 128 (FIG. 14A) for analysis of the next PI/PO. If the block is determined not to have any more PI/POs in decision block 152, then flow proceeds to decision block 154, where it is determined whether or not any more blocks are available at the current level. If so, flow proceeds to process block 156 in which the method considers the next block and proceeds back to process block 126 (FIG. 14A). If it is determined in decision block 154 that no more blocks are available, then the sub-routine ends.

Any process descriptions or blocks in flow charts described herein can be configured as representing modules, segments, or portions of code which include one or more executable instructions for implementing specific logical functions or steps in the process, and alternate implementations are included within the scope of the embodiments of the present disclosure in which functions may be executed out of order from that shown or discussed, including substantially concurrently or in reverse order, depending on the functionality involved, as would be understood by those reasonably skilled in the art.

The test pattern generating methods can be configured in a computer program, which comprises an ordered listing of executable instructions for implementing logical functions. The computer program can be embodied in any computer-readable medium for use by an instruction execution system, apparatus, or device, such as a computer-based system, processor-controlled system, or other system that can fetch the instructions from the instruction execution system, apparatus, or device and execute the instructions. In the context of this document, a “computer-readable medium” can be any medium that can contain, store, communicate, propagate, or transport the program for use by the instruction execution system, apparatus, or device. In addition, the scope of the present disclosure includes the functionality of the herein-disclosed embodiments configured with logic in hardware and/or software mediums.

It should be emphasized that the above-described embodiments are merely examples of possible implementations. Many variations and modifications may be made to the above-described embodiments without departing from the principles of the present disclosure. All such modifications and variations are intended to be included herein within the scope of this disclosure and protected by the following claims.

We claim:

1. A test pattern processing system for testing a device under test (DUT), the test pattern processing system comprising:
a memory operative to store a netlist of the DUT;
a bounded region detecting device in communication with the memory, the bounded region detecting device operative to detect, from the netlist, regions of the DUT bounded by control/observe points, at least one bounded region being embedded within another bounded region;
a sequence determining device in communication with the bounded region detecting device, the sequence determining device operative to determine, from the bounded regions, a sequencing scheme having a sequence in which the test patterns of embedded bounded regions are generated before the test patterns of bounded regions embedding the embedded bounded regions;
a test pattern generating device in communication with the memory, the bounded region detecting device, and the sequence determining device, the test pattern generating device operative to generate, according to the sequencing scheme, test patterns from the netlist of the bounded regions;
a test pattern memory in communication with the test pattern generating device, the test pattern memory operative to store the test patterns generated by the test pattern generating device; and
a test pattern supplying device in communication with the test pattern memory and the sequence determining device, the test pattern supplying device operative to retrieve the stored test patterns from the test pattern memory and supply the test patterns according to the sequencing scheme.

2. The test pattern processing system of claim 1, wherein the test pattern generating device is further operative to receive testability features defining the location of the scan inputs, scan outputs, scan enable, and scan clock on the DUT.

3. The test pattern processing system of claim 1, wherein the control/observe points comprise at least one of primary input ports, primary output ports, and scannable flip-flops.

4. The test pattern processing system of claim 1, wherein the sequence determining device determines the layering scheme based on the layers of embedding of bounded regions within larger bounded regions.

5. The test pattern processing system of claim 4, wherein the test pattern generating device is further operative to generate test patterns for the most deeply embedded bounded regions in the first layer before generating test patterns for the bounded regions embedding the embedded bounded regions in subsequent layers.

6. The test pattern processing system of claim 1, wherein the test pattern supplying device is further operative to supply the test patterns to automatic testing equipment (ATE).

7. A test pattern processing system comprising:
means for receiving a netlist of a device under test (DUT);
means for detecting, from the netlist, regions bounded by control/observe points, at least one bounded region embedded within another bounded region;
means for determining, from the bounded regions, a sequencing scheme having a sequence in which the test patterns of embedded bounded regions are generated before the test patterns of embedding bounded regions; and
means for generating, according to the sequencing scheme, test patterns from the netlist of the bounded regions.

8. The test pattern processing system of claim 7, further comprising:
means for storing the generated test patterns; and
means for supplying the stored test patterns to automatic testing equipment (ATE).

9. The test pattern processing system of claim 7, wherein the means for determining the sequencing scheme further comprises means for determining a sequencing scheme based on the layers of bounded regions embedded within larger bounded regions.

10. The test pattern processing system of claim 9, wherein the means for generating test patterns further comprises:
means for generating test patterns on the most deeply embedded bounded regions;
means for generating test patterns on the next higher layer with the netlist of the lower layers disregarded and the test patterns from the lower layers inserted; and
means for repeating the generating of test patterns on the next higher layer until the top layer has been reached.

11. The test pattern processing system of claim 7, wherein the means for generating test patterns further comprises means for receiving testability features defining the location of the scan inputs, scan outputs, scan enable, and scan clock on the DUT.

12. A test pattern generating device comprising:
a first input operative to receive testability features of a device under test (DUT);
a second input operative to receive a netlist that models the DUT;
a third input operative to receive a map of the regions of the DUT that are bounded by control/observe points;
a fourth input operative to receive a sequencing scheme defining the sequence in which test patterns of the bounded regions are to be generated; and
an output operative to transmit test patterns for testing the DUT.

13. The test pattern generating device of claim 12, wherein:
the second input is in communication with a memory;
the third input is in communication with a bounded region detecting device;
the fourth input is in communication with a sequence determining device; and
the output is in communication with a test pattern memory.

14. A method for generating test patterns used for testing a device under test (DUT), the method comprising:
receiving a netlist of the DUT;
detecting regions of the DUT bounded by control/observe points, at least one bounded region being embedded within a larger bounded region;
determining a sequencing scheme that defines a sequence in which test patterns of the bounded regions are to be generated, the sequencing scheme starting at the lowest layer of the most deeply embedded bounded region;
generating test patterns of the bounded regions at the lowest layer;
storing the generated test patterns;
disregarding the netlist of the bounded regions from which test patterns are generated;
generating test patterns of bounded regions at the next higher layer with the stored test patterns from the lower layers inserted therein and the netlist of the lower layers disregarded; and
repeating the storing and generating of test patterns of bounded regions at the next higher layers with the netlist of the lower layers eliminated until the top layer is reached.

15. The method of claim 14, wherein receiving a netlist comprises:
receiving a structural gate-level model of the components of the DUT; and
receiving a plan of the connectivity between the components.

16. The method of claim 14, wherein detecting the regions bounded by control/observe points comprises detecting the regions encircled by at least one of primary input ports, primary output ports, and scanned flip-flops.

17. A method for generating test patterns, the method comprising:
receiving a netlist of a device under test (DUT), the netlist comprising regions bounded by control/observe points, at least one bounded region embedded within another bounded region; and
generating test patterns for the bounded regions using a sequence starting with a deeply embedded bounded region.

18. The method of claim 17, wherein generating test patterns further comprises simultaneously generating test patterns for bounded regions embedded at the same depth.

19. The method of claim 17, wherein generating test patterns further comprises generating test patterns for at least one bounded region that embeds at least one other bounded region, such that the netlist of the embedded bounded region is disregarded and the test patterns of the embedded bounded region is incorporated therefor.

20. A method for generating test patterns, the method comprising:
receiving a netlist of a hierarchically-designed device under test (DUT), the netlist comprising blocks, at least one block embedded within another block; and
generating test patterns for the blocks using a sequence starting with a deeply embedded block.

21. The method of claim 20, wherein generating test patterns further comprises determining whether or not the blocks are bounded by control/observe points.

22. The method of claim 21, wherein, when a block is determined to be bounded by control/observe points, generating test patterns for the block comprises:
performing an automatic test pattern generator (ATPG) run on the block;
storing the test pattern results; and
disregarding the netlist of the tested block in a higher-level block that embeds the tested block.

23. The method of claim 21, wherein, when a block is determined not to be bounded by control/observe points, generating test patterns for the block comprises:
adding the netlist of the block to a higher-level block, the block being embedded by the higher-level block; and
augmenting the test patterns at the higher-level to accommodate the netlist of the block that is not bounded by control/observe points.

24. A computer program, stored on a computer-readable medium, for generating test patterns, the computer program comprising:
logic configured to receive a netlist of a device under test (DUT), the netlist comprising regions bounded by control/observe points, at least one bounded region embedded within another bounded region; and
logic configured to generate test patterns for the bounded regions using a processing sequence that starts with a deeply embedded bounded region.

25. The computer program of claim 24, wherein the logic configured to generate test patterns is further configured to receive testability features defining the location of scan inputs, scan outputs, a scan enable, and a scan clock on the DUT.

26. The computer program of claim 24, further comprising:
logic configured to detect the location of regions bounded by control/observe points;
logic configured to determine the processing sequence in which the test patterns are generated;
logic configured to store the generated test patterns; and
logic configured to retrieve stored test patterns and to supply the test patterns according to the processing sequence.

27. The computer program of claim 26, wherein the logic configured to determine the processing sequence is configured to determine a layering scheme based on the layers of embedding of bounded regions within larger bounded regions.

28. The computer program of claim 26, wherein the logic configured to retrieve and supply test patterns is further configured to supply test patterns to automatic testing equipment (ATE).
